(19) United States
(12) Patent Application Publication
(10) Pub. No.: US 2026/0164913 A1
(43) Pub. Date: Jun. 11, 2026

(54) LIGHT SENSING DEVICE

(71) Applicant: VisEra Technologies Company Ltd., Hsin-Chu City (TW)

(72) Inventors: Wei-Hsiang LIN, Hsin-Chu City (TW); Hsuan-Chun CHANG, Hsin-Chu City (TW); Chin-Chuan HSIEH, Hsin-Chu City (TW)

(21) Appl. No.: 19/339,133

(22) Filed: Sep. 24, 2025

Related U.S. Application Data
(60) Provisional application No. 63/728,872, filed on Dec. 6, 2024.

(51) Int. Cl. H10K 30/81; G01J 3/02; G01J 3/28; G01J 3/50; H10K 30/60; H10K 30/85; H10K 30/86

(52) U.S. Cl. CPC H10K 30/81; G01J 3/0275; G01J 3/2803; G01J 3/50; H10K 30/60; H10K 30/85; H10K 30/86

(57) ABSTRACT

A light sensing device includes a light receiver that has a first organic photodetector (OPD) unit. The first OPD unit includes a bottom electrode unit, a first transport layer disposed on the bottom electrode unit, an active layer disposed on the first transport layer, a second transport layer disposed on the first active layer, and a top electrode disposed on the second transport layer. The first OPD unit generates a plurality of sensing currents in response to an input light received by the first OPD unit and a plurality of voltages that are applied on the bottom electrode unit simultaneously or sequentially. The light sensing device further includes a processor coupled to the light receiver.

### CROSS-REFERENCE TO RELATED APPLICATION

The present application claims priority to U.S. Provisional patent application No. 63/728,872 , filed on Dec. 6, 2024, which is incorporated by reference herein in its entirety.

### BACKGROUND

### Technical Field

The present disclosure relates to technology related to a light sensing device. More particularly, the present disclosure relates to the light sensing device employing neural network model for spectrum analysis.

### Description of Related Art

Multi-channel hyperspectral image sensor technology employs designs where a known transmitter (Tx) and a filter array work together to isolate specific wavelengths of light. A receiver (Rx), composed of an array of sensor pixels, then captures the filtered light. Each pixel is designed to respond to a specific portion of the spectrum, thereby generating a multi-channel hyperspectral image.

### SUMMARY

An aspect of the disclosure provides a light sensing device includes a light receiver that has a first organic photodetector (OPD) unit. The first OPD unit includes a bottom electrode unit, a first transport layer disposed on the bottom electrode unit, an active layer disposed on the first transport layer, a second transport layer disposed on the first active layer, and a top electrode disposed on the second transport layer. The first OPD unit generates a plurality of sensing currents in response to an input light received by the first OPD unit and a plurality of voltages that are applied on the bottom electrode unit simultaneously or sequentially. The light sensing device further includes a processor coupled to the light receiver.

In some embodiments, the bottom electrode unit includes a bottom electrode array including a plurality of bottom electrodes. Each one of the plurality of voltages is applied on one of the plurality of bottom electrodes simultaneously.

In some embodiments, the first OPD unit further includes a first electron donating layer interposed between the first transport layer and the active layer, and a second electron donating layer interposed between the second transport layer and the top electrode. The first electron donating layer and the second electron donating layer are self-assembled monolayers.

In some embodiments, the bottom electrode unit includes a bottom electrode. The plurality of voltages is applied on the bottom electrode sequentially. The plurality of voltages differ from each other by less than 1 Volt.

In some embodiments, the First OPD unit further includes a first electron donating layer interposed between the first transport layer and the active layer, and a second electron donating layer interposed between the second transport layer and the top electrode.

In some embodiments, a thickness of the first electron donating layer and the second electron donating layer is smaller than 2 nanometers.

In some embodiments, the plurality of voltages are negative voltages, the first transport layer is hole transport layer, and the second transport layer is electron transport layer.

In some embodiments, the plurality of voltages are positive voltages, the first transport layer is electron transport layer, and the second transport layer is hole transport layer.

In some embodiments, the processor is configured to identifying wavelength information of the input light by: recording current values of the plurality of sensing currents and voltage values of the plurality of voltages; generating a current-voltage curve that plots the current values against the voltage values; and inputting the current-voltage curve to a neural network model.

In some embodiments, the processor performs the neural network model to: extract graphical features of the current-voltage curve; categorize the current-voltage curve into an identified spectrum in a plurality of spectra based on the extracted graphical features of the current-voltage curve, and generate the wavelength information of the input light, including a central wavelength of the identified spectrum.

In some embodiments, a wavelength range of each group in the plurality of predefined spectra is less than or equal to 20 nanometers.

In some embodiments, the light receiver further includes a plurality of second OPD units. The first OPD and the plurality of second OPD units are arranged as an array and share the same top electrode.

An aspect of the disclosure provides an operational method for a light sensing device that includes operations: generating, by a first organic photodetector (OPD) unit of in a light receiver, a plurality of first sensing currents in response to an input light received by the first OPD unit and a plurality of first voltages that are applied on a bottom electrode unit of the first OPD unit simultaneously or sequentially; transmitting, by the light receiver, the plurality of first sensing currents and the plurality of first voltages to a processor; and identifying wavelength information of the input light by the processor. The operation of identifying the wavelength information of the input light by the processor includes generating a first current-voltage curve based on first current values of the plurality of first sensing currents against first voltage values of the plurality of first voltages; and performing, by the processor, a neural network model to: extract graphical features of the first current-voltage curve, categorize the first current-voltage curve into a first identified spectrum in a plurality of spectra based on the extracted graphical features of the first current-voltage curve, and generating the wavelength information of the input light based on the first identified spectrum.

In some embodiments, the operational method further includes operation of generating, by a second OPD unit of the light receiver, a plurality of second sensing currents to the processor in response to the input light received by the second OPD unit and the plurality of first voltages that are applied on a second bottom electrode unit of the second OPD unit simultaneously or sequentially. Generating the first current-voltage curve further includes summing second current values of the plurality of second sensing currents with the first current values at the first voltage values to generate a plurality of sum sensing current values and generating the first current-voltage curve that plots the plurality of sum sensing current values against the first voltage values.

In some embodiments, the operational method further includes operation of filtering, by a first filter and a second filter, the input light into a first filtered light and a second filtered light respectively, wherein the first OPD unit receives the first filtered light as the input light; and generating, by a second OPD unit of the light receiver, a plurality of second sensing currents to the processor in response to the second filtered light received by the second OPD unit and the plurality of first voltages that are applied on a second bottom electrode unit of the second OPD unit simultaneously or sequentially. Identifying wavelength information of the input light further includes generating a second current-voltage curve that plots second current values of the plurality of second sensing currents against the first voltage values of the plurality of first voltages; and performing, by the processor, the neural network model to: extract graphical features of the second current-voltage curve, and categorize the second current-voltage curve into a second identified spectrum in the plurality of spectra based on the extracted graphical features of the second current-voltage curve. The first identified spectrum and the second identified spectrum are different from each other. Generate the wavelength information of the input light further includes generating the wavelength information comprising a central wavelength of the first identified spectrum and a central wavelength of the second identified spectrum.

In some embodiments, the operational method further includes operation of generating, by a second OPD unit of the light receiver, a plurality of second sensing currents to the processor in response to the input light received by the second OPD unit and a plurality of second voltages that are applied on a second bottom electrode unit of the second OPD unit simultaneously or sequentially. A voltage range of the plurality of second voltages is different from a voltage range of the plurality of first voltage. Generating the first current-voltage curve further includes generating the first current-voltage curve that plots the first current values against the first voltage values and also plots second current values of the plurality of second sensing currents against second voltage values of the plurality of second voltages.

In some embodiments, the operational method further includes operation of filtering, by a first filter and a second filter, the input light into a first filtered light and a second filtered light respectively, wherein a first OPD group, including the first and second OPD units, receives the first filtered light as the input light; and generating, by a second OPD group of the light receiver, a plurality of third sensing currents to the processor in response to the second filtered light received by the second OPD group and the plurality of first and second voltages that are applied on third bottom electrode units of the second OPD group simultaneously or sequentially. Identifying wavelength information of the input light further comprises: generating a second current-voltage curve that plots third current values of the plurality of third sensing currents against the first voltage values and the second voltage values; and performing, by the processor, the neural network model to: extract graphical features of the second current-voltage curve, and categorize the second current-voltage curve into a second identified spectrum in the plurality of spectra based on the extracted graphical features of the second current-voltage curve. The first identified spectrum and the second identified spectrum are different from each other. Generate the wavelength information of the input light further comprises: generating the wavelength information comprising a central wavelength of the first identified spectrum and a central wavelength of the second identified spectrum.

In some embodiments, the plurality of first voltages differ from each other by less than 1 Volt, and the plurality of second voltages differ from each other by less than 1 Volt.

In some embodiments, the bottom electrode unit of the first OPD unit includes a bottom electrode array having a plurality of bottom electrodes. Generating the plurality of first sensing currents in response to the input light and the plurality of first voltages includes applying each of the plurality of first voltages on one of the plurality of bottom electrodes simultaneously.

In some embodiments, the bottom electrode unit of the first OPD unit includes a bottom electrode. Generating the plurality of first sensing currents in response to the input light and the plurality of first voltages includes applying the plurality of first voltages on the bottom electrode sequentially.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a light sensing device, according to some embodiments of the present disclosure.

FIG. 2 is a schematic diagram of part of the light receiver corresponding to FIG. 1, according to some embodiments of the present disclosure.

FIG. 3 is a schematic diagram of an organic photodetector unit in a top view, according to some embodiments of the present disclosure.

FIG. 4 is a schematic diagram of an organic photodetector unit corresponding to line AA′ in FIG. 3 in a cross-sectional view, according to some embodiments of the present disclosure.

FIG. 5 is a schematic diagram of an organic photodetector unit corresponding to line AA′ in FIG. 3 in a cross-sectional view, according to some embodiments of the present disclosure.

FIG. 6 is a schematic diagram of an organic photodetector unit in a top view, according to some embodiments of the present disclosure.

FIG. 7 is a schematic diagram of an organic photodetector unit corresponding to FIG. 6 in a cross-sectional view, according to some embodiments of the present disclosure.

FIG. 8 is a schematic diagram of an organic photodetector unit corresponding to FIG. 6 in a cross-sectional view, according to some embodiments of the present disclosure.

FIG. 9A illustrates schematic steps for wavelength determination, according to some embodiments of the present disclosure.

FIG. 9B is a flow chart of an operational method for a light sensing device determining wavelength of an input light, according to some embodiments of the present disclosure.

FIGS. 9C to 9F are flow charts illustrating additional operations of the operational method of FIG. 9B, according to some embodiments of the present disclosure.

FIG. 10 is a flow chart of a method of training a neural network model, according to some embodiments of the present disclosure.

FIG. 11 is a graph illustrating external quantum efficiency versus wavelength and voltage, according to some embodiments of the present disclosure.

FIG. 12 is a graph illustrating external quantum efficiency (EQE) versus wavelength and voltage, according to some embodiments of the present disclosure.

FIG. 13 is a graph illustrating normalized EQE values versus wavelength and voltage, according to some embodiments of the present disclosure.

FIG. 14 is a graph illustrating normalized EQE values versus wavelength and voltage, according to some embodiments of the present disclosure.

FIG. 15 is a graph illustrating normalized EQE values versus wavelength and voltage, according to some embodiments of the present disclosure.

FIG. 16 illustrates grouping of wavelengths versus voltage, according to some embodiments of the present disclosure.

FIG. 17 is a schematic diagram of a light receiver, according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the present disclosure, “connected” or “coupled” may refer to “electrically connected” or “electrically coupled.” “Connected” or “coupled” may also refer to operations or actions between two or more elements.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

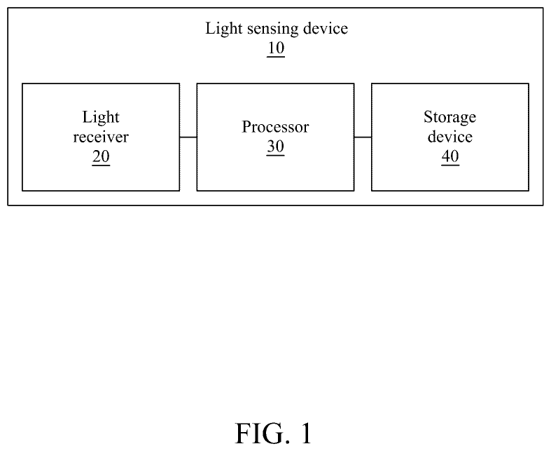

Reference is now made to FIG. 1. FIG. 1 is a schematic diagram of a light sensing device 10, according to some embodiments of the present disclosure. For illustration, the light sensing device 10 includes a light receiver 20, a processor 30, and a storage device 40. In some embodiments, the light receiver 20 is operationally coupled to the processor 30, and the processor 30 is operationally coupled to the storage device 40.

In some embodiments, the processor 30 includes any suitable processor, such as a conventional central process unit (CPU, microcontroller (MCU), general processor circuit, operating in conjunction with any suitable operating system, such as Windows XP, Unix, or Linux.

The storage device 40 includes any appropriate memory accessible to the processor 30, such as a random access memory (RAM) or other suitable storage system, for storing codes that are read for perform specific operation in the present application. In particular, the storage device 40 includes a fast access memory for storing and receiving information and is suitably configured with sufficient capacity to facilitate the operation of performing neural network model by the processor 30.

In some embodiments, the neural network model performed by the processor 30 is a deep learning neural network that consists of interconnected layers of nodes, designed to learn from large datasets including complex spectral signals. The neural network can be implemented by, for example, Convolutional Neural Networks (CNNs), which excel in processing grid-like data, and any other suitable models.

In some embodiments of operation, the light sensing device 10 is configured to analyze lights exposed to the light receiver 20 that generates sensing currents correspondingly. For example, the light receiver 20 includes at least one organic photodetector unit that is configured to generate sensing currents in response to the input light and voltages applied thereto. The processor 30 performs the neural network model according to codes stored in the storage device 40 to identify wavelength information of the input light in accordance with the sensing currents and voltages. The detailed structural configurations of the light sensing device 10 and the operations will be discussed in the following paragraphs.

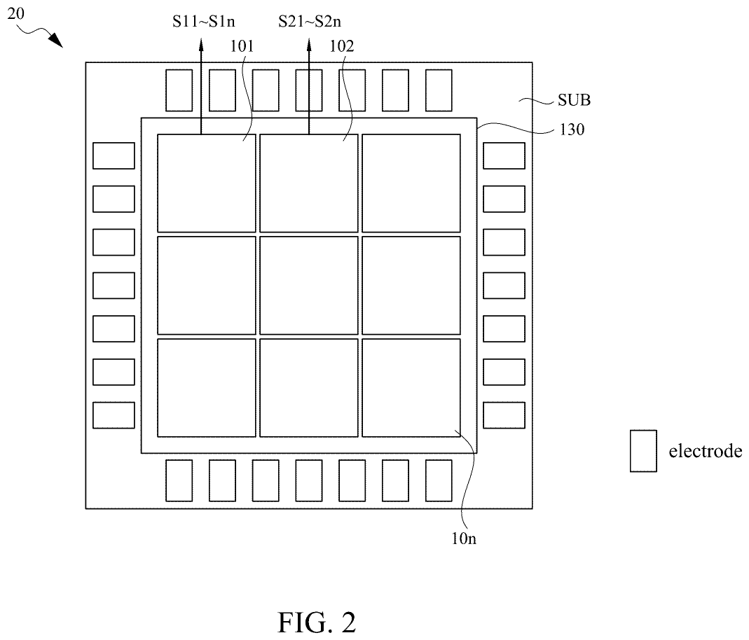

Reference is now made to FIG. 2. FIG. 2 is a schematic diagram of part of the light receiver corresponding to FIG. 1, according to some embodiments of the present disclosure.

For illustration, the light receiver 20 includes organic photodetector units 101 to 10n that are disposed on a substrate SUB in a form of array. In some embodiments, the organic photodetector units 101 to 10n share a top electrode. In some embodiments, the organic photodetector units 101 to 10n generate sensing currents in response to the input light. For example, the organic photodetector unit 101 outputs sensing currents S11-S1n, and the organic photodetector unit 102 outputs sensing currents S21-S2n, and so on. The light receiver 20 further includes electrodes surrounding the organic photodetector units 101 to 10n for retrieving from or transmitting to the organic photodetector units 101 to 10n the signals in operation of the light receiver 20. In some embodiments, the organic photodetector units 101 to 101n have similar configurations. In some embodiments, the organic photodetector units 101 to 101n have the same structural configuration and operational configurations.

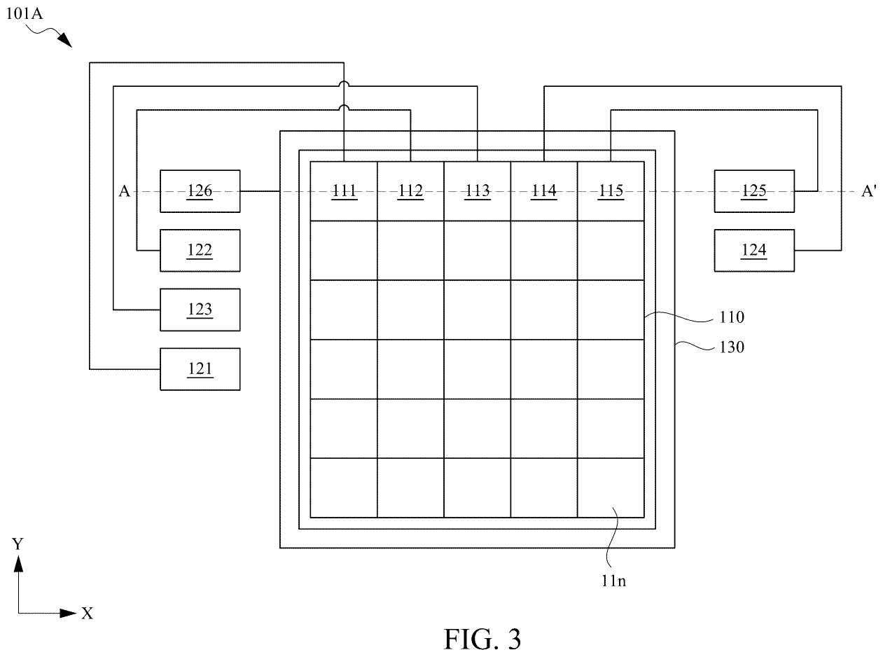

Reference is now made to FIG. 3. FIG. 3 is a schematic diagram of an organic photodetector unit 101A in a top view, according to some embodiments of the present disclosure. In some embodiments, the organic photodetector unit 101A is configured with respect to, for example, the organic photodetector unit 101 of FIG. 2.

As illustratively shown in FIG. 3, the organic photodetector unit 101A includes a bottom electrode array 110 composed of multiple bottom electrodes 111 to 11n arranged in rows and columns. In some embodiments, the bottom electrodes 111 to 11n are in shape of square. In some embodiments, one in the bottom electrodes 111 to 11n is coupled to a corresponding electrode. For example, the bottom electrode 111 is coupled to the electrode 121, and the bottom electrode 112 is coupled to the electrode 122, and so on. The top electrode 130 is coupled to the electrode 126. The configurations of other bottom electrodes are similar to the bottom electrode 111. Hence, the repetitious descriptions are omitted here. The electrodes 121 to 126 are given for the purposes of illustration. Other electrodes coupled to the bottom electrodes are not shown.

In some embodiments, the organic photodetector unit 101A further includes a top electrode 130 disposed above and cover the whole bottom electrode array 110.

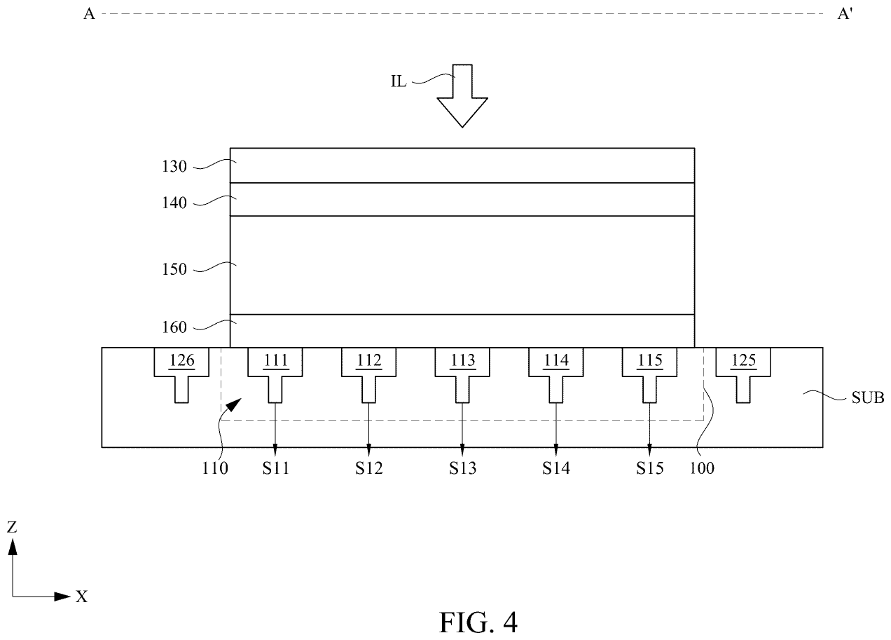

Reference is now made to FIG. 4. FIG. 4 is a schematic diagram of the organic photodetector unit 101A corresponding to line AA′ in FIG. 3 in a cross-sectional view, according to some embodiments of the present disclosure.

As shown in FIG. 4, the organic photodetector unit 101A further includes a transport layer 140, an active layer 150, and a transport layer 160. For illustration, the transport layer 160 is disposed on the bottom electrode array 110 including the bottom electrodes 111-115. The bottom electrode array 110 is included in a bottom electrode unit 100 in the substrate SUB. The active layer 150 is disposed on the transport layer 160. The transport layer 140 is disposed on the active layer 150, and the top electrode 130 disposed on the transport layer 140.

In some embodiments, the top electrode 130 and the bottom electrodes in the bottom electrode array 110 are formed as a layer having a thickness in a first range, for example, approximately 100 nm to 300 nm. The transport layers 140 and 160 have a thickness in a second range smaller than the first range, for example, approximately 40 nm to 60 nm. The active layer 150 sandwiched between the transport layers 140 and 160 has a thickness in a third range larger than the first range, for example, approximately 3 um to 10 um. Alternatively stated, a ratio of a thickness of the active layer 150 over a thickness of the transport layer 140 and the transport layer 160 ranges from 10 to 20.

In some embodiments, the bottom electrodes in the bottom electrode array 110 are made of metal, such like, copper (Cu), silver (Ag), gold (Au), aluminum (Al), or any other suitable material.

The top electrode 130 is made of conductive film materials, such like, transparent conducting oxides (TCO), high-conductivity polymers (e.g., PEDOT), carbon nanotubes (CNT), silver nanowires, grapheme, or any other suitable material. In some embodiments, the top electrode 130 has conductivity that exceeds 100 Siemens per centimeter (S/cm).

The transport layer 140 is configured as an electron transport layer (ETL) and made of inorganic semiconductors, such like, Titanium dioxide (TiO2), zinc oxide (ZnO) or any other suitable material. The transport layer 160 is configured as a hole transport layer (HTL) and made of metal oxide, such like, Nickel Oxide (NiO), Molybdenum Trioxide (MoO₃), or any other suitable material.

The active layer 150 is made of semiconductor mixed material including electron donor and electron acceptor.

According to some embodiments of operation, when the input light IL is received by to the light receiver 20 and absorbed by the active layer 150, it creates excitons that separate into free charge carriers—electrons and holes. The transport layer 140 efficiently transports electrons to the top electrode 130 (configured as the cathode and grounded in some embodiment) while the transport layer 160 directs holes to the bottom electrodes in the bottom electrode array 110 (configured as the anodes). In some embodiments, the bottom electrodes receive different voltage applied thereto in order to transmit sensing currents according to the holes.

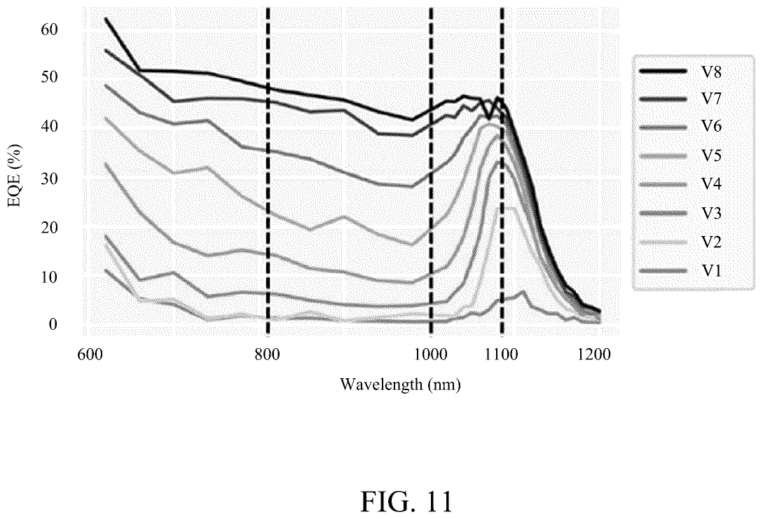

For example, with reference to both FIGS. 3 to 4 and FIG. 11, the bottom electrodes 111 to 115 receive voltages V1 to V5 at the same time respectively, in which the voltages V1 to V5 are 0V, −2V, −4V, −6V, and −8V according to some embodiments. The bottom electrodes 111 to 115 are configured as anodes to have zero or negative voltage to attract holes and to generate corresponding sensing currents S11 to S15. In some embodiments, the amount of generated sensing current is influenced by the light's intensity, as higher light intensity results in more excitons and subsequently more charge carriers, leading to a stronger electrical sensing current. Additionally, the wavelength of the light affects the absorption efficiency of the active layer, as shown in FIG. 11. Certain wavelengths may produce stronger responses depending on the material properties, which can enhance or diminish the overall signal output. In some embodiments, the processor 30 further analyzes the sensing currents to obtain wavelength information of the input light IL.

The configurations of FIG. 4 are given for illustrative purposes. Various implements are within the contemplated scope of the present disclosure. For example, in some embodiments, voltage values of the voltages are given for example, and can be other suitable values according to the actual application of the present application, for example, in a range from 0V to −18 V. Moreover, in some embodiments, a number of the bottom electrodes having various voltages is not limited to 5 and can be other suitable number, for example, at least 8 bottom electrodes in the bottom electrode array 110 to receiving 8 different voltages. Values of the thickness of the top electrode 130, the transport layer 140, the active layer 150, and the transport layer 160 are given for example, and can be other suitable values according to the actual application of the present application.

In some embodiments, compared with the embodiments of FIG. 4, the transport layer 160 (i.e., HTL) is interposed between the active layer 150 and the top electrode 130, while the transport layer 140 (i.e., ETL) is interposed between the active layer 150 and the substrate SUB. In such arrangements, zero or positive voltages are applied on the bottom electrodes in the bottom electrode array 110.

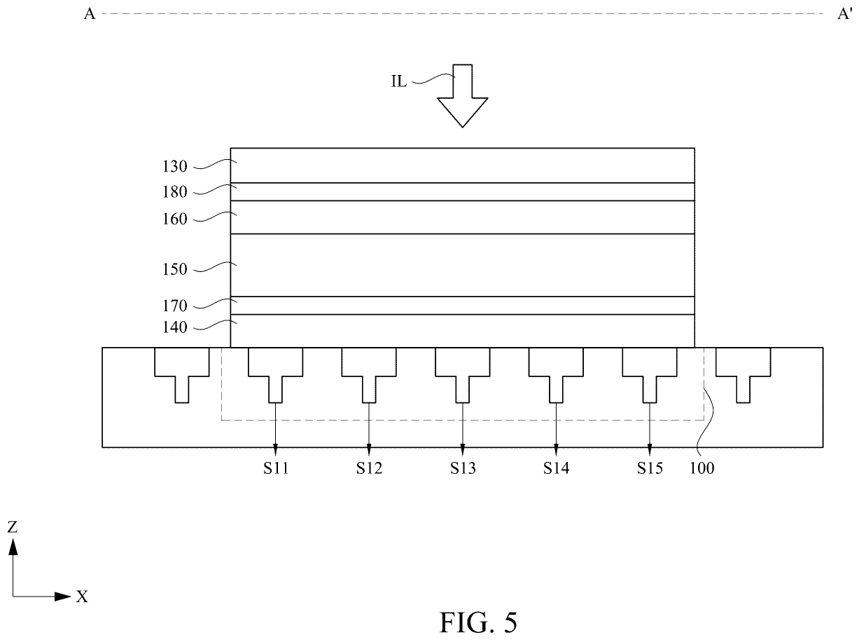

Reference is now made to FIG. 5. FIG. 5 is a schematic diagram of an organic photodetector unit 101A corresponding to line AA′ in FIG. 3 in a cross-sectional view, according to some embodiments of the present disclosure. With respect to the embodiments of FIGS. 1 to 4, like elements in FIG. 5 are designated with the same reference numbers for ease of understanding. The specific operations of similar elements, which are already discussed in detail in above paragraphs, are omitted herein for the sake of brevity.

Compared with the embodiments of FIG. 4, the transport layer 140 configured as the ETL layer is interposed between the active layer 150 and the substrate SUB, and the organic photodetector unit 101A in FIG. 5 further includes an electron donating layer 170 interposed between the transport layer 140 and the active layer 150. The transport layer 160 configured as the HTL layer is interposed between the active layer 150 and the top electrode 130, and the organic photodetector unit 101A further includes an electron donating layer 180 interposed between the top electrode 130 and the transport layer 160.

In some embodiments, the electron donating layer 170 and the electron donating layer 180 are self-assembled monolayers (SAMs). In some embodiments, when the positive voltages are applied to the bottom electrode array 110, the electron donating layer 170 is configured as a charge transport interface, facilitating electron transfer to the bottom electrodes, while the electron donating layer 180 is configured as another charge transport interface, facilitating electrons escape from the transport layer 160 and the active layer 150 to the bottom electrodes. Accordingly, it improves response speed of the organic photodetector unit 101A. In the embodiments FIG. 5, the thickness of the active layer 150 is in a range around 500 nm to 1 um.

The configurations of FIG. 5 are given for illustrative purposes. Various implements are within the contemplated scope of the present disclosure. For example, in some embodiments, compared with the embodiments of FIG. 4, positions of the transport layer 160 (i.e., HTL) and the transport layer 140 (i.e., ETL) switch, and in such arrangements, zero or negative voltages are applied on the bottom electrodes in the bottom electrode array 110.

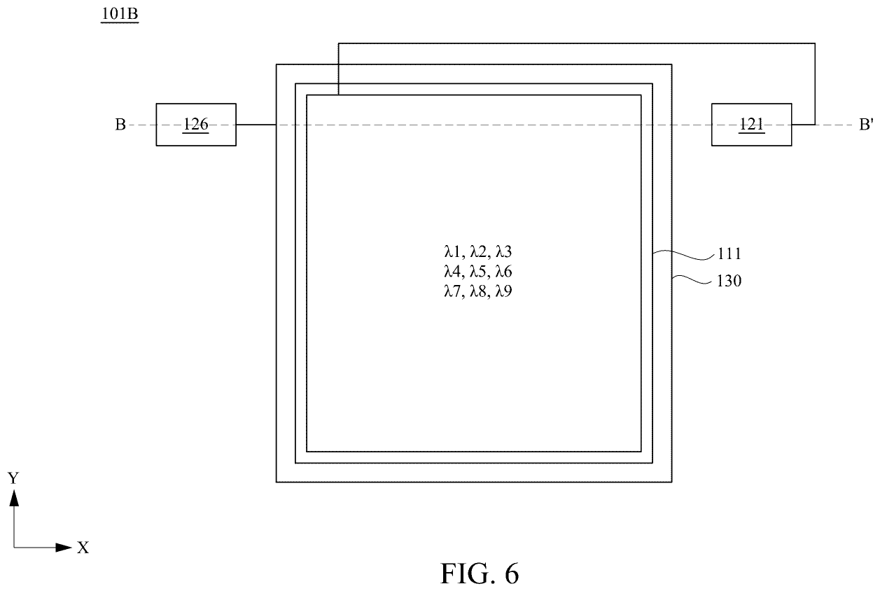

Reference is now made to FIG. 6. FIG. 6 is a schematic diagram of an organic photodetector unit 101B in a top view, according to some embodiments of the present disclosure. In some embodiments, the organic photodetector unit 101B is configured with respect to, for example, the organic photodetector unit 101A of FIG. 3.

Compared with the organic photodetector unit 101A of FIG. 3, instead of having the bottom electrode array 110 for the single organic photodetector unit 101A, the organic photodetector unit 101B includes the single bottom electrode 111 in the bottom electrode unit 100, as shown in FIG. 6.

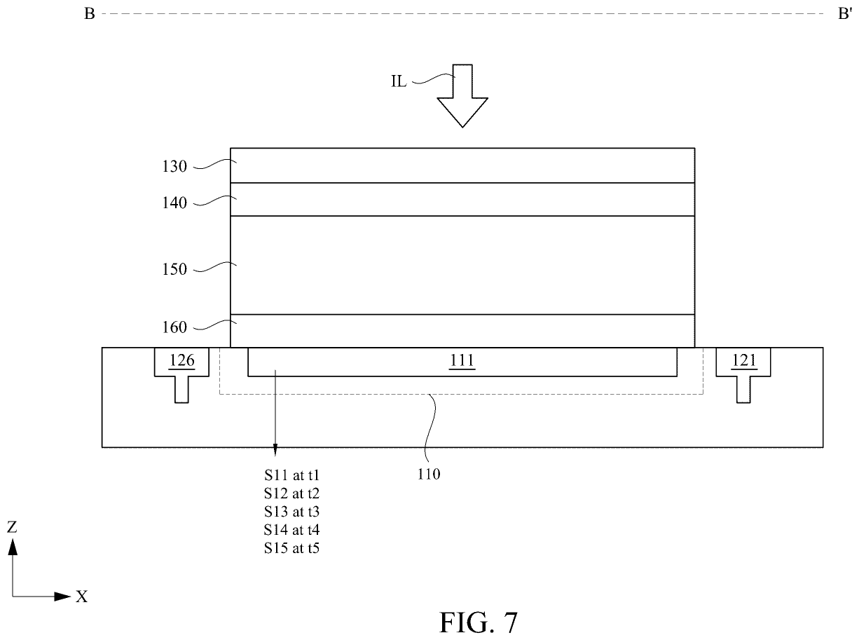

Reference is now made to FIG. 7. FIG. 7 is a schematic diagram of the organic photodetector unit 101B corresponding to line BB′ in FIG. 6 in a cross-sectional view, according to some embodiments of the present disclosure. With respect to the embodiments of FIGS. 3 to 5, like elements in FIG. 7 are designated with the same reference numbers for ease of understanding.

In some embodiments of operation, the bottom electrode 111 receives the voltages V1 to V5 sequentially at the different time points t1 to t5 to transmit corresponding sensing currents S11 to S15. The bottom electrode 111 is configured as anodes to have zero or negative voltage to attract holes.

The configurations of FIG. 7 are given for illustrative purposes. Various implements are within the contemplated scope of the present disclosure. For example, in some embodiments, positions of the transport layer 160 (i.e., HTL) and the transport layer 140 (i.e., ETL) switch, and in such arrangements, zero or positive voltages are applied on the bottom electrode 111.

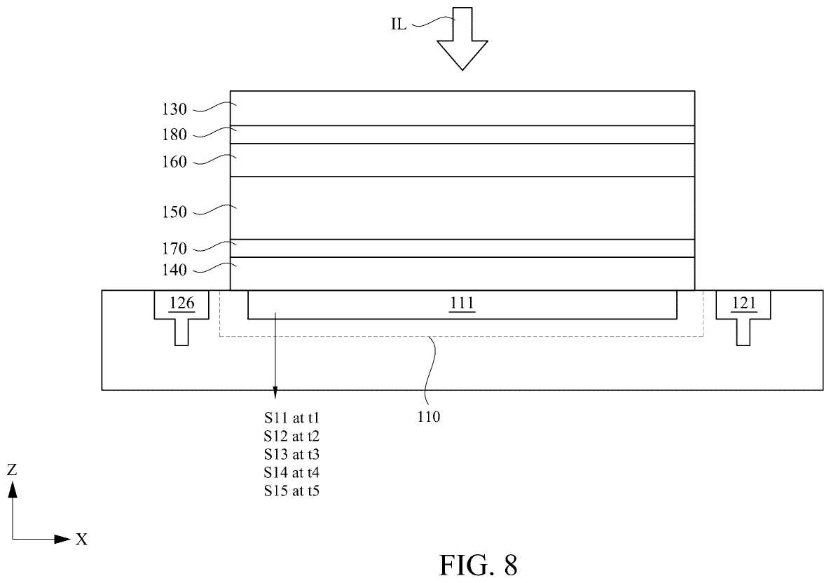

Reference is now made to FIG. 8. FIG. 8 is a schematic diagram of the organic photodetector unit 101B corresponding to line BB′ in FIG. 6 in a cross-sectional view, according to some embodiments of the present disclosure. With respect to the embodiments of FIGS. 3 to 5, like elements in FIG. 8 are designated with the same reference numbers for ease of understanding.

Compared with the embodiments of FIG. 5, the organic photodetector unit 101B in FIG. 8 includes single bottom electrode 111 disposed below the transport layer 140 to receive the positive voltages V1 to V5 at the different time points t1 to t5 to generate corresponding sensing currents S11 to S15.

In some embodiments, the electron donating layer 170 and the electron donating layer 180 are self-assembled monolayers (SAMs) and have a thickness less than approximately 2 nanometers.

The configurations of FIG. 8 are given for illustrative purposes. Various implements are within the contemplated scope of the present disclosure. For example, in some embodiments, positions of the transport layer 160 (i.e., HTL) and the transport layer 140 (i.e., ETL) switch, and in such arrangements, zero or negative voltages are applied on the bottom electrode 111.

The configurations shown in FIGS. 6-8 enable miniaturization of the organic photodetector unit by using a single bottom electrode to retrieve sensing currents at different voltages.

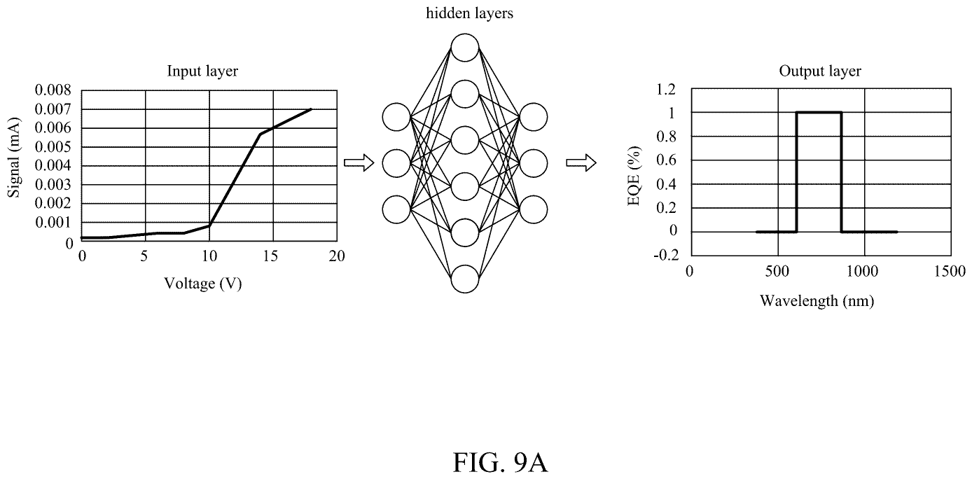

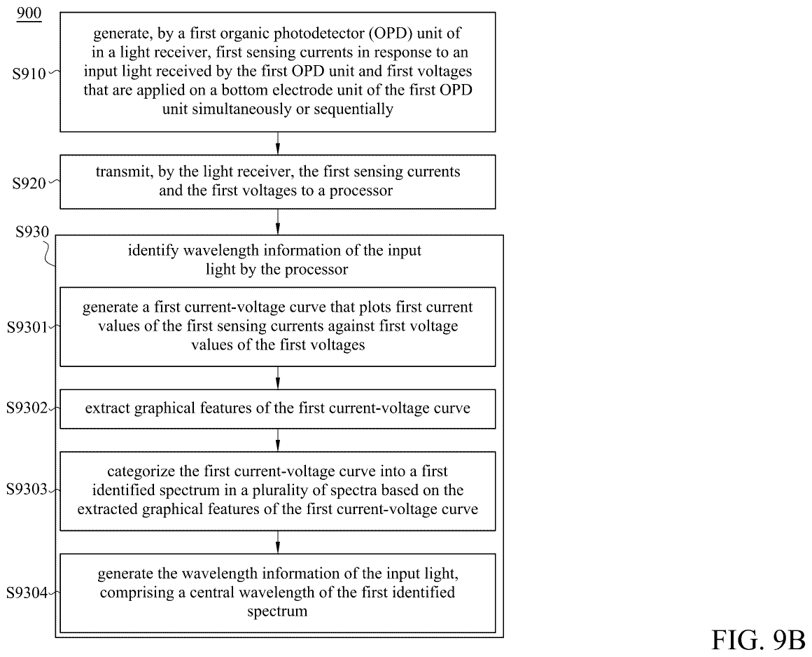

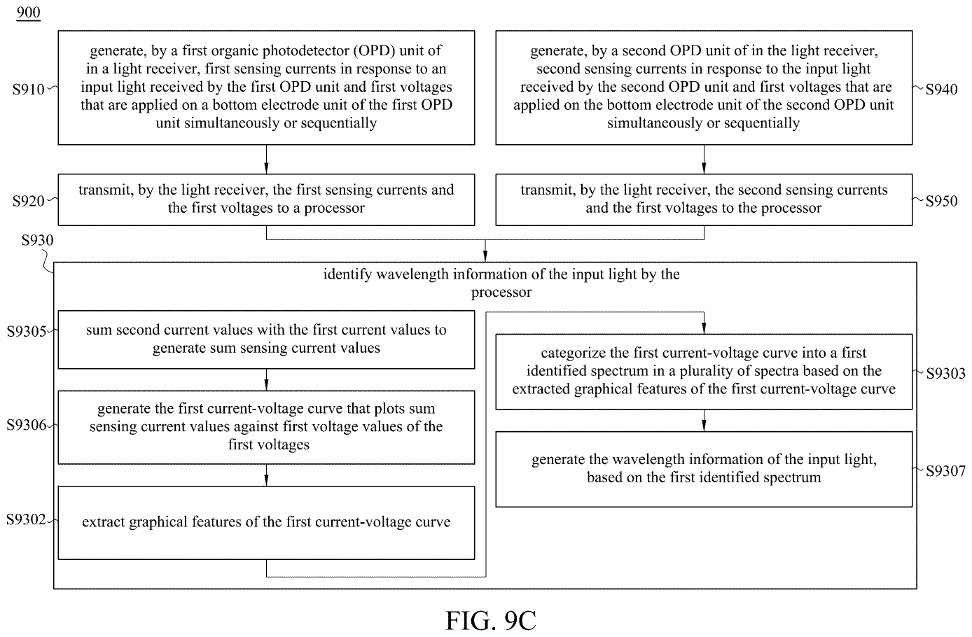

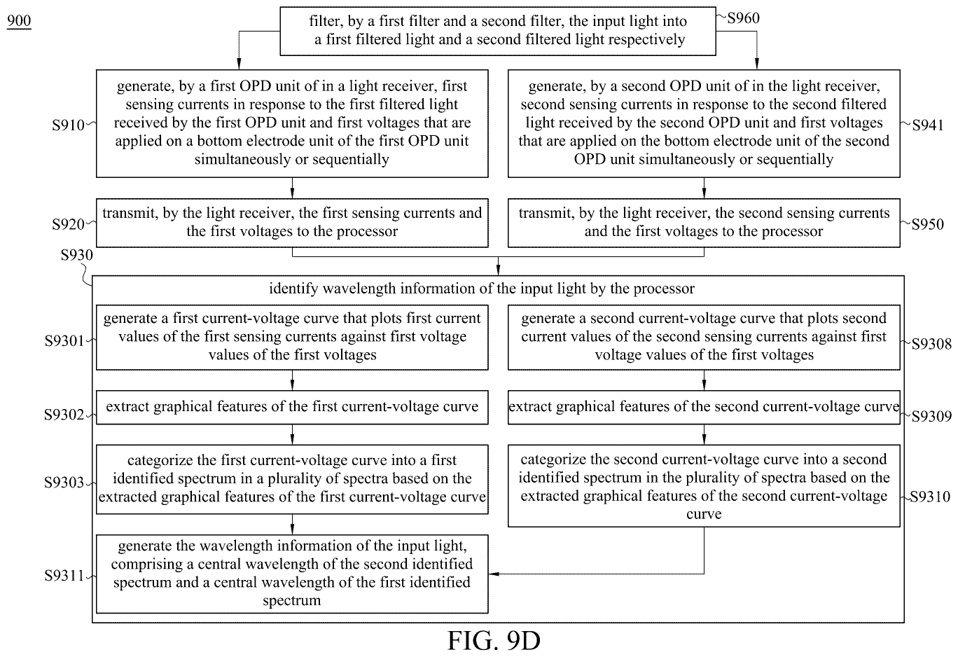

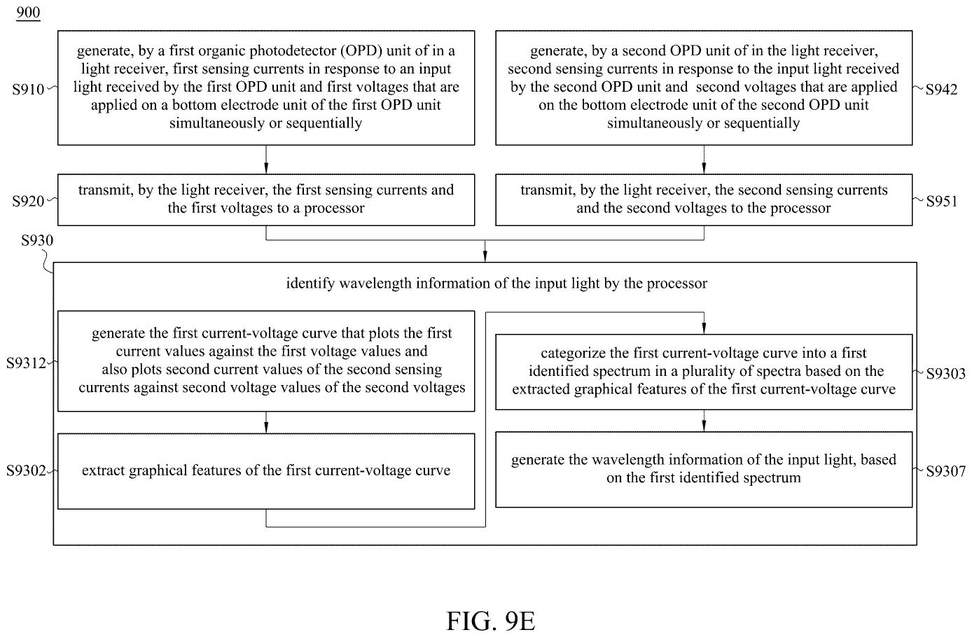

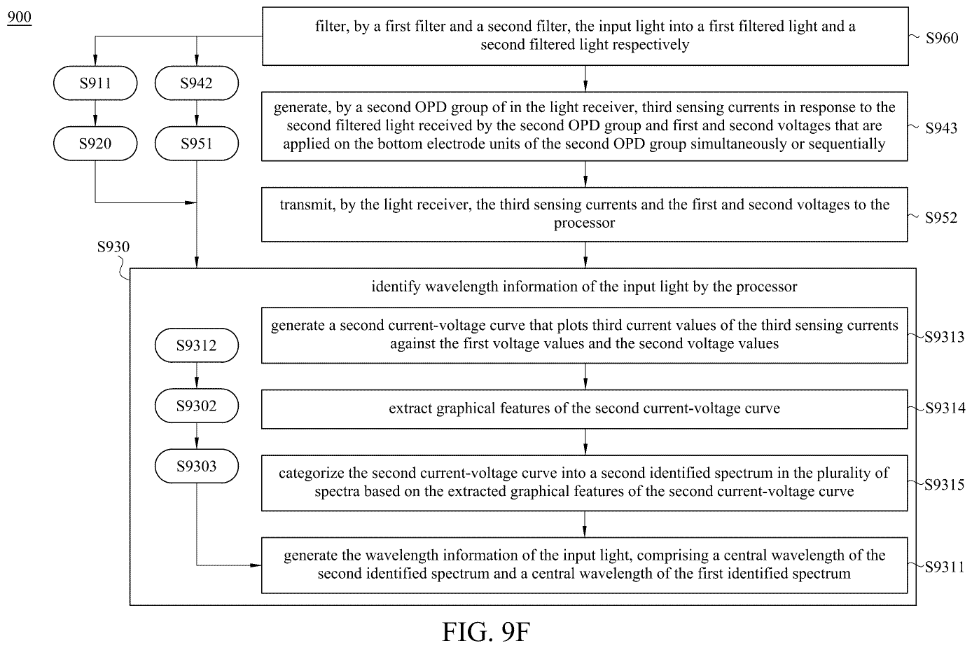

In application of the light sensing device 10 according to some embodiments, the sensing currents generated by the organic photodetector units in response to the input light IL are provided to the processor 30 for determining the wavelength information of the input light IL. As illustrated in FIG. 9A that illustrates steps for wavelength determination, the processor 30 performs, according to the received sensing currents and corresponding voltages, the neural network model to categorize current-voltage curve into one of predefined spectra. Specifically, FIG. 9B is a flow chart of an operational method for a light sensing device determining wavelength of an input light, in which the light sensing device can be implemented by, for example, the light sensing device 10 in embodiments of FIG. 1 to FIG. 8. It is understood that additional operations can be provided before, during, and after the processes shown by FIG. 9B, and some of the operations described below can be replaced or eliminated, for additional embodiments of the method. The order of the operations/processes may be interchangeable. Throughout the various views and illustrative embodiments, like reference numbers are used to designate like elements. The method 900 includes operations that are described below with reference to the light sensing device 10 in FIG. 1 to FIG. 8 and embodiments in FIG. 11 to FIG. 17.

With reference to both FIG. 9A and FIG. 9B, in operation S910, the organic photodetector unit, for example, 101 in FIG. 2 of in the light receiver 20 generates first sensing currents S11-S1n in response to the input light IL received by the organic photodetector unit 101 and voltages V11-V1n. The voltages V11-V1n can be applied simultaneously on the bottom electrode unit 100 including the bottom electrode array 110 as shown in the embodiments of FIG. 3 to FIG. 5. In other embodiments as shown in FIG. 6 to FIG. 8, the voltages V11-V1n can be applied on the bottom electrode unit 100 including a single bottom electrode 111 sequentially.

In operation S920, the light receiver 20 transmits the sensing currents and the voltages to the processor 30.

In operation S930, the processor 30 identifies wavelength information of the input light IL, which includes operations S9301-S9304. According to operation S9301, as shown in FIG. 9A, the processor 30 generates current-voltage curve that plots current values of the sensing currents S11-S1n against voltage values of the voltages V11-V1n. In some embodiments, the processor 30 firstly records the current values of the sensing currents S11-S1n and the voltage values of the voltages V11-V1n and further generates the current-voltage curve accordingly. In some embodiments, the method 900 further includes operation of inputting the current-voltage curve to a neural network model performed by the processor 30 for analysis.

Specifically, in the embodiments of FIG. 9A, data of the current-voltage curve are converted into external quantum efficiency (EQE) versus voltage and further received at the input layer of the neural network model. In some embodiments, the EQE indicates the ratio of the number of charge carriers collected by the organic photodetector unit 101 to the number of photons of a given energy shining on the organic photodetector unit 101 from outside (incident photons). For illustration, as shown in the current-voltage curve of FIG. 9A, the voltage values of the voltages V11-V1n range from 0 to around 18 Volts, and the current values of the sensing currents S11-S1n range from 0 to around 0.007 mA. The data of the current-voltage curve are converted into the EQE in percentage versus voltage.

In operation S9302, the hidden layers of interconnected neural nodes in the neural network model perform graphical feature extraction of the current-voltage curve.

Next, in operation S9303, the neural network model categorizes the current—voltage curve into an identified spectrum from a plurality of spectra, based on the previously extracted graphical features. For example, a current—voltage curve with certain graphical features is categorized into the identified spectrum corresponding to wavelengths λa to λb. Another curve with different graphical features is categorized into the another identified spectrum corresponding to wavelengths λc to λd. In some embodiments, wavelength range of each spectrum (e.g., wavelengths from λa to λb) is less than or equal to 20 nanometers (nm), but the present application is not limited thereto.

In operation S9304, the neural network model generates the wavelength information for the input light IL, which includes the central wavelength of the identified spectrum. For example, when the range of the identified spectrum is 20 nm (e.g., from 740 nm to 760 nm), the neural network model determines a central wavelength (e.g., 750 nm) for the wavelength information of the input light IL.

In some embodiments, the light sensing device 10 identifies the wavelength of the input light by one or more in the organic photodetector units 101 to 10n. Taking organic photodetector units 101 and 102 as example, in some embodiments, the organic photodetector units 101 and 102 have the same structural configuration as shown in one of embodiments in FIGS. 4-5 and FIGS. 7-8. In the embodiments of the organic photodetector units 101 and 102 having bottom electrode array, as shown in FIGS. 4-5, the voltages within the first voltage range are applied on the bottom electrode arrays of the organic photodetector units 101 and 102. In the embodiments of the organic photodetector units 101 and 102 having single bottom electrode, as shown in FIGS. 7-8, the voltages within the first voltage range are applied on the bottom electrodes of the organic photodetector units 101 and 102.

Reference is now made to FIG. 9C for discussion on multiple organic photodetector units operation. Compared with the embodiments of FIG. 9B, addition operation S940 is performed that the organic photodetector unit, for example, 102 in FIG. 2 of in the light receiver 20 generates second sensing currents S21-S2n in response to the input light IL received by the organic photodetector unit 102 and voltages V11-V1n. The voltages V11-V1n can be applied simultaneously on the bottom electrode unit 100 including the bottom pad array 110 as shown in the embodiments of FIG. 3 to FIG. 5. In other embodiments as shown in FIG. 6 to FIG. 8, the voltages V11-V1n can be applied on the bottom electrode unit 100 including a single bottom pad 111 sequentially.

In operation S950, the light receiver 20 transmits the sensing currents S21-S2n and the voltages V11-V1n to the processor 30.

The operation S930 further includes operations S9305-S9307. In operation S9305, the processor 30 sums current values of the sensing currents S21-S2n with current values of the sensing currents S11-S1n to generate sum sensing current values. With this configuration, greater sensing current intensity is achieved for accuracy of wavelength identification.

Then, in operation S9306, the processor 30 generates the current-voltage curve that plots sum sensing current values against voltage values of the voltages V11-V1n. Sequentially, the processor 30 further performs operations S9302-S9303 as discussed above.

After the operation S9303, operation S9307 is performed to generate, by the processor 30, the wavelength information of the input light, based on the first identified spectrum. For instance, according to the embodiments of the input light IL of a monochromatic light, the neural network model determines a central wavelength for the wavelength information of the input light IL.

In other embodiments, the current-voltage curve is categorized into the identified spectrum which is a combination of two sub-spectrum SSA (e.g., λA±10 nm) and SSB (e.g., λB±10 nm). In operation S9307, the neural network model determines that the wavelength information of the input light IL includes a central wavelength λA of the sub-spectrum SSA and a central wavelength λB of the sub-spectrum SSB.

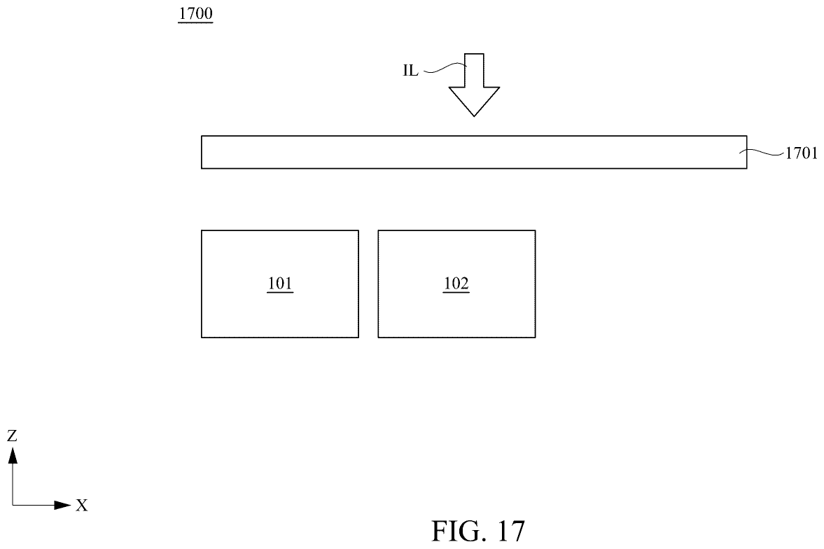

Reference is now made to FIGS. 9D and 17. FIG. 9D is a flow chart illustrating additional operations of the operational method 900 of FIG. 9B, according to some embodiments of the present disclosure. FIG. 17 is a schematic diagram of a light receiver 1700, according to some embodiments of the present disclosure. With respect to the embodiments of FIG. 1 to FIG. 9D, like elements in FIG. 17 are designated with the same reference numbers for ease of understanding. In some embodiments, the light receiver 1700 is configured with respect to, for example, the light receiver 20.

As shown in FIG. 17, the light receiver 1700 further includes a filter structure 1701 disposed above the organic photodetector units. In some embodiments, the filter structure 1701 is specifically designed to allow light of certain spectra of light to pass through for sensing by the organic photodetector units while blocking others.

For example, according to some embodiments, the filter structure 1701 may include multiple filters, in which each of them allow light of a certain spectrum of light to pass through.

In operation S960, two different filters in the filter structure 1701 filter the input light IL into a first filtered light and a second filtered light respectively. In some embodiments, the first filter may install right above the one of the OPD unit, for example, the organic photodetector unit 101. Likewise, the second filter may install right above another of the OPD unit, for example, the organic photodetector unit 102. Accordingly, the first filter may allow light of wavelength ranging from, for example, 600 to 800 nm to pass through and shine on the organic photodetector unit 101. The second filter may allow light of wavelength ranging from, for example, 800 to 1000 nm to pass through and shine on the organic photodetector unit 102.

The organic photodetector unit 101 and the light receiver 20 perform operations S910 and S920 to transmit the generated sensing currents and corresponding voltages to the processor 30. The processor 30 further performs operations S9301-S9303.

Similarly, according to operation S941, the organic photodetector unit 102 generates second sensing currents S21-S2n in response to the second filtered light and the voltages V11-V1n that are applied on the bottom electrode unit hereof simultaneously or sequentially. Then, operation S950 is performed.

After the processor 30 receives the second sensing currents S21-S2n the voltages V11-V1n, operations S9308 to S9311 are performed.

Specifically, in operation S9308, the processor 30 generates a second current-voltage curve that plots second current values of the second sensing currents against voltage values of the voltages V11-V1n.

In operation S9309, the hidden layers of interconnected neural nodes in the neural network model perform graphical feature extraction of the second current-voltage curve.

In operation S9310, the neural network model categorizes the second current-voltage curve into a second identified spectrum based on the previously extracted graphical features. In some embodiments, the neural network model determines the similarity of the second current-voltage curve with respect to data corresponding to wavelength of the second filter, which provides a faster operational speed of the neural network model.

Subsequently, after operations S9303 and S9310, the processor 30 generates the wavelength information of the input light IL including a central wavelength of the first identified spectrum and a central wavelength of the second identified spectrum. For example, the first current-voltage curve is categorized into the first identified spectrum ranging from 740 to 760 nm, and the first current-voltage curve is categorized into the first identified spectrum ranging from 800 to 820 nm. Accordingly, the wavelength information includes a central wavelength 750 nm of the first identified spectrum and a central wavelength 810 of the second identified spectrum.

According to other embodiments of the method 900, applying various voltages on multiple organic photodetector units increases the resolution of current-voltage curve, which improves accuracy of wavelength identification. The discussion will be conducted with reference to FIG. 9E, which is flow chart illustrating additional operations of the operational method of FIG. 9B, according to some embodiments of the present disclosure.

In the embodiments of FIG. 9E, two organic photodetector units cooperate in generating a current-voltage curve by receiving two different voltage ranges that together cover the necessary voltage range for wavelength identification. For example, the required voltage range for wavelength identification is from 0 to 18 Volts. Therefore, the voltage applied to the organic photodetector units 101 and 102 ranges from 0 to 9 Volts and from 9.1 to 18 Volts, respectively. The configurations of applied voltage are given for illustrative purposes. Various implements are within the contemplated scope of the present disclosure.

Compared with embodiments in FIG. 9C, the organic photodetector unit 102 performs operation S942 to generate second sensing currents in response to the input light and second voltages that are applied on the bottom electrode unit thereof simultaneously or sequentially. Then, in operation, the second sensing currents and the second voltages are transmitted to the processor 30.

During identifying wavelength information of the input light of operation S930, the processor 30 performs operation S9312 to generate a current-voltage curve that plots the first current values of the first sensing currents from the organic photodetector unit 101 against the first voltage values of applied voltages on the organic photodetector unit 101 and also plots the second current values of the second sensing currents from the organic photodetector unit 102 against the second voltage values of applied voltages on the organic photodetector unit 102.

After obtaining the current-voltage curve, the processor 30 performs operations S9302, S9303, and S9307 sequentially to obtain the wavelength information. The configurations are similar to those illustrated in the embodiments to FIG. 9C. Hence, the repetitious descriptions are omitted here.

Reference is now made to FIG. 9F. As in the aforementioned embodiments, multiple organic photodetector units are operationally grouped to generate a single current-voltage curve. In some embodiments, configuring several groups of organic photodetector units, each with a corresponding filter, enhances both the resolution of current-voltage curve and accuracy of wavelength identification.

With respect to the embodiments of FIGS. 9D-9E, the first group in FIG. 9F, including the organic photodetector units 101-102, performs operations S911 and S920, and operations S942, and S951, respectively, in response to the first filtered light obtained in operation S960.

On the other hand, in operation S943, another group of organic photodetector units generates third sensing currents in response to the second filtered light and applied voltages. The applied voltages have the same range as those applied to the first group of organic photodetector units and are applied on the bottom electrode units of the second group simultaneously and sequentially.

In operation S952, the third sensing currents and the first and second voltages are transmitted to the processor 30.

For identifying the wavelength information of the input light by the processor 30 in operation S930, similar to that in FIG. 9E, the first group performs operations S912, S9302 and S9303 sequentially. The operation S930 further includes operation S9313 to S9315. Specifically, in operation S9313, the processor 30 generates a second current-voltage curve that plots current values of the third sensing currents against the first voltage values and the second voltage values.

Sequentially, according to operation S9314, the hidden layers of interconnected neural nodes in the neural network model perform graphical feature extraction of the second current-voltage curve.

In operation S9315, the neural network model categorizes the second current-voltage curve into a second identified spectrum based on the previously extracted graphical features.

Following operations S9303 and S9315 as shown in FIG. 9F, the processor 30 generates the wavelength information of the input light IL, including central wavelengths of the first and second identified spectra.

The configurations of FIG. 9A to FIG. 9F are given for illustrative purposes. Various implements are within the contemplated scope of the present disclosure. For example, in some embodiments, the voltages and the range thereof are given as examples and can be modified based on the actual practice of the present application. In some embodiments, the first voltages V11-V1n differ from each other by less than 1 Volt, and the second voltages V21-V2n differ from each other by less than 1 Volt. In yet embodiment, number of organic photodetector units in an operational group can be more than two, designed for the actual application of the light sensing device 10. In other embodiments, the wavelength range of the filters is also adjustable to suit the specific usage of the light sensing device 10 with regard to the input light IL.

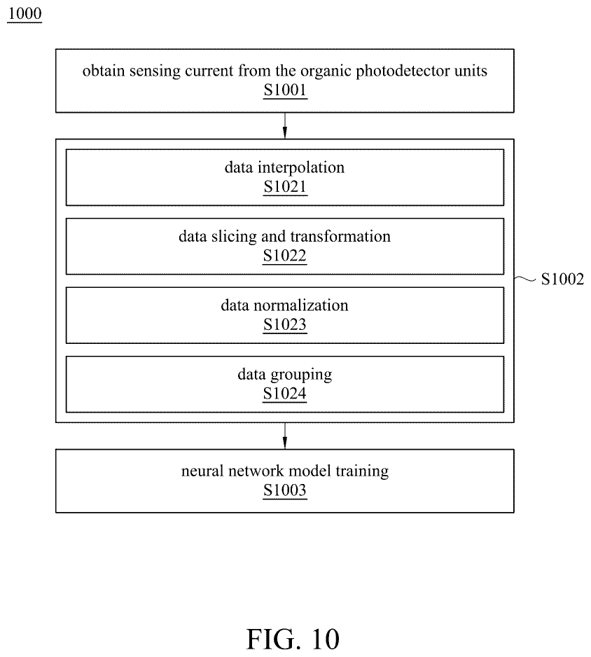

The neural network model described above and implemented by the processor 30 is well trained based on training data associated with input lights that cover wide-ranging wavelengths and voltages within a suitable range, applied to the bottom electrode unit. Training of the neural network model implemented in the light sensing device 10 will be discussed with reference to FIG. 10 to FIG. 16. FIG. 10 is a flow chart of a method 1000 of training a neural network model, according to some embodiments of the present disclosure. It is understood that additional operations can be provided before, during, and after the processes shown by FIG. 10, and some of the operations described below can be replaced or eliminated, for additional embodiments of the method. The order of the operations/processes may be interchangeable. Throughout the various views and illustrative embodiments, like reference numbers are used to designate like elements. The method 1000 has operations S1001-S1003 and will be discussed with reference to embodiments of FIG. 1 to FIG. 16.

In operation S1001, after the light receiver 20 senses lights of various wavelengths in a range, for example, 600 nm to 1200 nm as shown in FIG. 11, with various voltages for each wavelength of light, the processor 30 obtains data of the sensing currents from the organic photodetector units and corresponding data of the voltages. In some embodiments, the voltages for obtaining the sensing currents differ from any other by less than 1 Volt in order to obtain current-voltage curve suitable for analysis.

In some embodiments, the sensing currents differ from any other by less than 1 Volt. For example, FIG. 11 is a graph illustrating EQE versus wavelength and voltage, according to some embodiments of the present disclosure, in which the EQE is converted from the sensing currents.

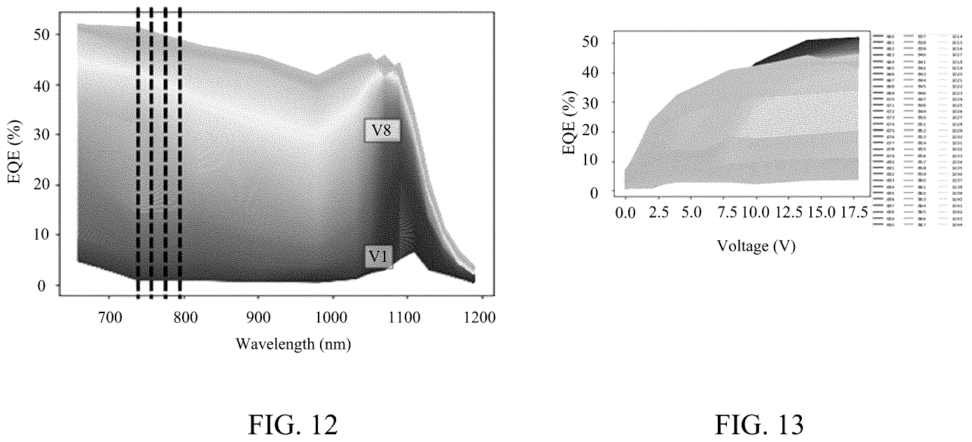

In operation S1002, data preparation by the processor 30 is performed and includes at least three operations S1021 to S1024. In operation S1021, as shown in FIG. 12, new data points are constructed within the range of a discrete set of known data points provided in FIG. 11.

In operation S1022, data slicing and transformation is performed. Specifically, vertical slices of FIG. 12 are converted into individual lines on the EQE versus voltage plot, each representing a unique wavelength, as shown in FIG. 13.

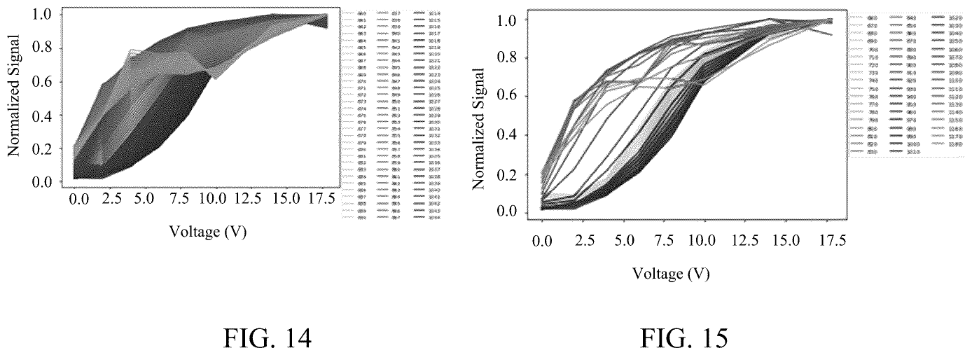

In operation S1023, as shown in FIG. 14, by normalizing the EQE values on the y-axis, the turning points and features of each curve become more distinct, improving the performance of the neural network model.

In operation S1024, data grouping is performed as shown in FIG. 15. Specifically, multiple adjacent lines within a certain spectral range in FIG. 14 are grouped together and be represented by a specific wavelength-central wavelength. In some embodiments, a number of 10 to 1000 curves in training dataset form a group referred to as a “spectrum”. This enhances the neural network model's ability to identify that specific wavelength. The configurations of present applications not only account for the potential fluctuation of future measurement readings, but also provide the neural network model with more specific wavelength characteristic curves to learn from. Accordingly, the learning and judgment capabilities are significantly improved by learning from multiple lines representing a single wavelength, compared to learning from a single line per wavelength.

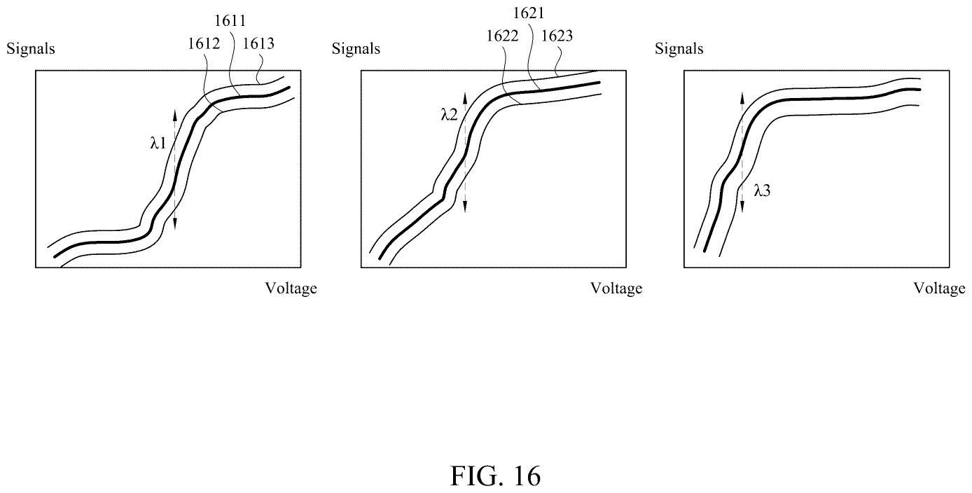

For example, in FIG. 16, an input plot 1611 lies within a specified wavelength range bounded by plots 1612 and 1613, where the plot 1612 corresponds to the lower boundary (e.g., 800 nm) and the plot 1613 corresponds to the upper boundary (e.g., 820 nm) of the first spectrum. The input plot 1611 is thus determined and represented by a central wavelength λ1 (e.g., 810 nm). Similarly, an input plot 1621 lies within a specified wavelength range bounded by plots 1622 and 1623., where the plot 1622 corresponds to the lower boundary (e.g., 500 nm) and the plot 1623 corresponds to the upper boundary (e.g., 520 nm) of the second spectrum. The input plot 1621 is thus determined and represented by a central wavelength λ2 (e.g., 510 nm). As shown in FIG. 16, plots within three distinct spectra are referred to as wavelengths, λ1, λ2, and λ3. In some embodiments, for example, input plots that lie within the ±10 nm band around a central wavelength λm are regarded as representing the same central wavelength λm. Thus, any plot whose wavelength lies within ±10 nm of λm is treated as λm.

In operation S1003, the neural network model is trained to recognize data patterns between the EQE versus voltage plots and the wavelength. In some embodiments, starting with randomly initialized weights and biases, the neural network model predicts output wavelength compared to target (exact) wavelength using a loss function measuring error. Back-propagation calculates the error gradient, guiding parameter updates via optimization algorithms (e.g., Adam, SGD). This prediction-error-update cycle repeats across the training dataset (epochs). A validation data set tracks performance to avoid overfitting, ensuring generalization to new data. The operation S1003 stops when performance is satisfactory is met. In some embodiments, 80% of data are utilized for learning and validation, and rest 20% data are for testing the final model.

The configurations of FIG. 9A to FIG. 17 are given for illustrative purposes. Various implements are within the contemplated scope of the present disclosure. For example, in some embodiments, the training data is not limited to the EQE-voltage curves of monochromatic light; spectral responses to voltage under polychromatic illumination can also be used. This allows the neural network model to learn the relationship between polychromatic light spectra and voltage, enabling the light sensing device 10 to determine the spectral composition of incident light. For clarity, the embodiment of determining the wavelength of monochromatic light is used as an example, and the present application is not limited thereto.

In some embodiments of the present application, a single-channel, filter-free organic photodetector (OPD) device employs deep learning for hyperspectral applications. Unaware of the transmitter's light source, the receiver analyzes incoming light in a single snapshot using a large pre-established database. It achieves high prediction accuracy for unknown light wavelengths.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light sensing device, comprising:
a light receiver comprising a first organic photodetector (OPD) unit, comprises:
a bottom electrode unit;
a first transport layer disposed on the bottom electrode unit;
an active layer disposed on the first transport layer;
a second transport layer disposed on the active layer; and
a top electrode disposed on the second transport layer;
wherein the first OPD unit generates a plurality of sensing currents in response to an input light received by the first OPD unit and a plurality of voltages that are applied on the bottom electrode unit simultaneously or sequentially; and
a processor coupled to the light receiver.

2. The light sensing device of claim 1, wherein the bottom electrode unit comprises:
a bottom electrode array comprising a plurality of bottom electrodes,
wherein each one of the plurality of voltages is applied on one of the plurality of bottom electrodes simultaneously.

3. The light sensing device of claim 2, wherein the first OPD unit further comprises:
a first electron donating layer interposed between the first transport layer and the active layer; and
a second electron donating layer interposed between the second transport layer and the top electrode,
wherein the first electron donating layer and the second electron donating layer are self-assembled monolayers.

4. The light sensing device of claim 1, wherein the bottom electrode unit comprises:
a bottom electrode, wherein the plurality of voltages is applied on the bottom electrode sequentially,
wherein the plurality of voltages differ from each other by less than 1 Volt.

5. The light sensing device of claim 4, wherein the first OPD unit further comprises:
a first electron donating layer interposed between the first transport layer and the active layer; and
a second electron donating layer interposed between the second transport layer and the top electrode.

6. The light sensing device of claim 5, wherein a thickness of the first electron donating layer and the second electron donating layer is smaller than 2 nanometers.

7. The light sensing device of claim 1, wherein the plurality of voltages are negative voltages,
the first transport layer is hole transport layer, and
the second transport layer is electron transport layer.

8. The light sensing device of claim 1, wherein the plurality of voltages are positive voltages,
the first transport layer is electron transport layer, and
the second transport layer is hole transport layer.

9. The light sensing device of claim 1, wherein the processor is configured to identifying wavelength information of the input light by:
recording current values of the plurality of sensing currents and voltage values of the plurality of voltages;
generating a current-voltage curve that plots the current values against the voltage values; and
inputting the current-voltage curve to a neural network model.

10. The light sensing device of claim 9, wherein the processor performs the neural network model to:
extract graphical features of the current-voltage curve;
categorize the current-voltage curve into an identified spectrum in a plurality of spectra based on the extracted graphical features of the current-voltage curve, and
generate the wavelength information of the input light, comprising a central wavelength of the identified spectrum.

11. The light sensing device of claim 10, wherein a wavelength range of each spectrum in the plurality of spectra is less than or equal to 20 nanometers.

12. The light sensing device of claim 1, wherein the light receiver further comprises a plurality of second OPD units,
wherein the first OPD unit and the plurality of second OPD units are arranged as an array and share the same top electrode.

13. An operational method for a light sensing device, comprising:
generating, by a first organic photodetector (OPD) unit of in a light receiver, a plurality of first sensing currents in response to an input light received by the first OPD unit and a plurality of first voltages that are applied on a bottom electrode unit of the first OPD unit simultaneously or sequentially;
transmitting, by the light receiver, the plurality of first sensing currents and the plurality of first voltages to a processor; and
identifying wavelength information of the input light by the processor, comprising:
generating a first current-voltage curve based on first current values of the plurality of first sensing currents against first voltage values of the plurality of first voltages; and
performing, by the processor, a neural network model to:
extract graphical features of the first current-voltage curve,
categorize the first current-voltage curve into a first identified spectrum in a plurality of spectra based on the extracted graphical features of the first current-voltage curve, and
generate the wavelength information of the input light, based on the first identified spectrum.

14. The operational method of claim 13, further comprising:
generating, by a second OPD unit of the light receiver, a plurality of second sensing currents to the processor in response to the input light received by the second OPD unit and the plurality of first voltages that are applied on a second bottom electrode unit of the second OPD unit simultaneously or sequentially;
wherein generating the first current-voltage curve further comprises:
summing second current values of the plurality of second sensing currents with the first current values at the first voltage values to generate a plurality of sum sensing current values; and
generating the first current-voltage curve that plots the plurality of sum sensing current values against the first voltage values.

15. The operational method of claim 13, further comprising:
filtering, by a first filter and a second filter, the input light into a first filtered light and a second filtered light respectively, wherein the first OPD unit receives the first filtered light as the input light; and
generating, by a second OPD unit of the light receiver, a plurality of second sensing currents to the processor in response to the second filtered light received by the second OPD unit and the plurality of first voltages that are applied on a second bottom electrode unit of the second OPD unit simultaneously or sequentially;
wherein identifying wavelength information of the input light further comprises:
generating a second current-voltage curve that plots second current values of the plurality of second sensing currents against the first voltage values of the plurality of first voltages; and
performing, by the processor, the neural network model to:
extract graphical features of the second current-voltage curve, and
categorize the second current-voltage curve into a second identified spectrum in the plurality of spectra based on the extracted graphical features of the second current-voltage curve, wherein the first identified spectrum and the second identified spectrum are different from each other,
wherein generate the wavelength information of the input light further comprises:
generating the wavelength information comprising a central wavelength of the first identified spectrum and a central wavelength of the second identified spectrum.

16. The operational method of claim 13, further comprising:
generating, by a second OPD unit of the light receiver, a plurality of second sensing currents to the processor in response to the input light received by the second OPD unit and a plurality of second voltages that are applied on a second bottom electrode unit of the second OPD unit simultaneously or sequentially,
wherein a voltage range of the plurality of second voltages is different from a voltage range of the plurality of first voltages;
wherein generating the first current-voltage curve further comprises:
generating the first current-voltage curve that plots the first current values against the first voltage values and also plots second current values of the plurality of second sensing currents against second voltage values of the plurality of second voltages.

17. The operational method of claim 16, further comprising:
filtering, by a first filter and a second filter, the input light into a first filtered light and a second filtered light respectively,
wherein a first OPD group, including the first and second OPD units, receives the first filtered light as the input light; and
generating, by a second OPD group of the light receiver, a plurality of third sensing currents to the processor in response to the second filtered light received by the second OPD group and the plurality of first and second voltages that are applied on third bottom electrode units of the second OPD group simultaneously or sequentially;
wherein identifying wavelength information of the input light further comprises:
generating a second current-voltage curve that plots third current values of the plurality of third sensing currents against the first voltage values and the second voltage values; and
performing, by the processor, the neural network model to:
extract graphical features of the second current-voltage curve, and
categorize the second current-voltage curve into a second identified spectrum in the plurality of spectra based on the extracted graphical features of the second current-voltage curve, wherein the first identified spectrum and the second identified spectrum are different from each other,
wherein generate the wavelength information of the input light further comprises:
generating the wavelength information comprising a central wavelength of the first identified spectrum and a central wavelength of the second identified spectrum.

18. The operational method of claim 16, wherein the plurality of first voltages differ from each other by less than 1 Volt, and the plurality of second voltages differ from each other by less than 1 Volt.

19. The operational method of claim 13, wherein the bottom electrode unit of the first OPD unit comprises a bottom electrode array having a plurality of bottom electrodes,
wherein generating the plurality of first sensing currents in response to the input light and the plurality of first voltages comprises:
applying each of the plurality of first voltages on one of the plurality of bottom electrodes simultaneously.

20. The operational method of claim 13, wherein the bottom electrode unit of the first OPD unit comprises a bottom electrode,
wherein generating the plurality of first sensing currents in response to the input light and the plurality of first voltages comprises:
applying the plurality of first voltages on the bottom electrode sequentially.
